(19) United States
(12) Patent Application Publication
(10) Pub. No.: US 2023/0059253 A1
(43) Pub. Date: Feb. 23, 2023

(54) DISPLAY DEVICE

(71) Applicant: LG Display Co., Ltd., Seoul (KR)

(72) Inventors: JungSun BAEK, Paju-si (KR); Seongjoo LEE, Goyang-si (KR); ChangHyun SONG, Goyang-si (KR); Seungpyo HONG, Busan (KR)

(73) Assignee: LG Display Co., Ltd., Seoul (KR)

(21) Appl. No.: 17/863,177

(22) Filed: Jul. 12, 2022

(30) Foreign Application Priority Data
Aug. 18, 2021 (KR) 10-2021-0108795

(51) Int. Cl. H01L 27/32

(52) U.S. Cl. CPC H01L 27/3246; H01L 27/3223; H01L 51/56

(57) ABSTRACT

According to an aspect of the present disclosure, a display device includes a substrate including a plurality of sub-pixels, an overcoating layer on the substrate and including a base portion and a plurality of protrusions having a groove, a first electrode corresponding to each of the plurality of sub-pixels and covering the base portion and the plurality of protrusions, a bank on a portion of the first electrode, an organic layer on the first electrode and the bank, a second electrode on the organic layer, and a dummy organic layer and a dummy conductive layer in the groove. The groove can be disposed between the plurality of sub-pixels, and an end of the bank can overlap the groove.

### CROSS-REFERENCE TO RELATED APPLICATIONS

This application claims the benefit of and priority to Korean Patent Application No. 10-2021-0108795 filed on Aug. 18, 2021, in the Republic of Korea, the entire contents of which are hereby expressly incorporated by reference into the present application.

### BACKGROUND

### Technical Field

The present disclosure relates to a display device, and more particularly, to a display device capable of minimizing a leakage current at a side portion thereof.

### Discussion of the Related Art

Recently, as our society advances toward an information-oriented society, the field of display devices for visually expressing an electrical information signal has rapidly advanced. Various display devices having excellent performance in terms of thinness, lightness, and low power consumption, are being developed correspondingly.

Among these various display devices, a light emitting display device is a self-light emitting display device, and can be manufactured to be light and thin since it does not require a separate light source, unlike a liquid crystal display device having a separate light source.

In addition, the light emitting display device has advantages in terms of power consumption due to a low voltage driving, and is excellent in terms of a color implementation, a response speed, a viewing angle, and a contrast ratio (CR). Therefore, the light emitting display devices are expected to be utilized in various fields.

### SUMMARY OF THE DISCLOSURE

An aspect of the present disclosure is to provide a display device capable of minimizing a leakage current transmitted to a side portion thereof when the display device is driven.

Another aspect of the present disclosure is to provide a display device in which light emission of some light emitting elements (due to leakage current) among a plurality of light emitting elements having a common layer can be minimized.

Still another aspect of the present disclosure is to provide a display device capable of improving image display quality in low grayscale.

Objects of the present disclosure are not limited to the above-mentioned objects, and other objects, which are not mentioned above, can be clearly understood by those skilled in the art from the following descriptions.

A display device according to an exemplary embodiment of the present disclosure includes a substrate including a plurality of sub-pixels, an overcoating layer on the substrate and including a base portion and a plurality of protrusions having a groove, a first electrode corresponding to each of the plurality of sub-pixels and covering the base portion and the plurality of protrusions, a bank on a portion of the first electrode, an organic layer on the first electrode and the bank, a second electrode on the organic layer, and a dummy organic layer and a dummy conductive layer in the groove, wherein the groove is disposed between the plurality of sub-pixels, and wherein an end of the bank overlaps the groove.

A display device according to another exemplary embodiment of the present disclosure includes a substrate including a plurality of sub-pixels, an overcoating layer on the substrate and including a base portion and a plurality of protrusions, a first electrode corresponding to each of the plurality of sub-pixels and covering the base portion and the plurality of protrusions, a bank on a portion of the first electrode and formed of an inorganic material, an organic layer on the first electrode and the bank, and a second electrode on the organic layer, wherein a part of the plurality of protrusions includes a groove between the plurality of sub-pixels, and wherein an end of the bank is disposed to cover the groove at an outside of the groove.

Other detailed matters of the exemplary embodiments are included in the detailed description and the drawings.

According to the present disclosure, current leakage through a common layer of a plurality of light emitting elements can be minimized.

According to the present disclosure, color reproducibility can be improved by minimizing unintentional light emission of a light emitting element when driving a display device.

According to the embodiments of the present disclosure, it is possible to improve display quality by minimizing visual recognition of color abnormality or visible spot when displaying a low grayscale image.

The effects according to the present disclosure are not limited to the contents exemplified above, and more various effects are included in the present specification.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to an exemplary embodiment of the present disclosure.

FIG. 2 is a cross-sectional view of the display device taken along line II-II′ of FIG. 1.

FIGS. 3A to 3F are cross-sectional views sequentially illustrating a method of manufacturing a display device according to an exemplary embodiment of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings. All the components of each display device according to all embodiments of the present disclosure are operatively coupled and configured.

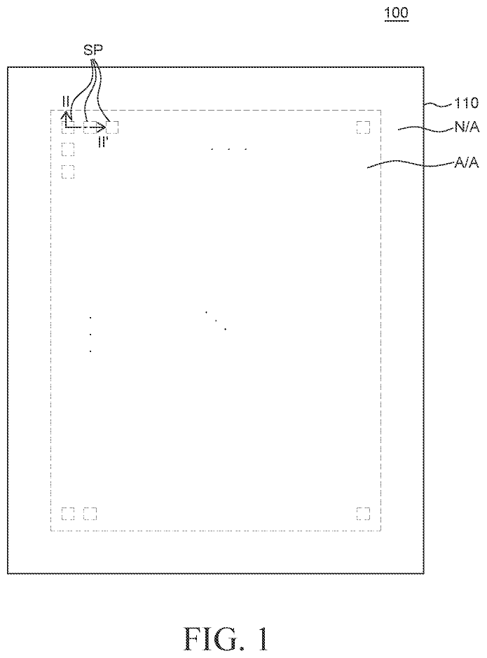

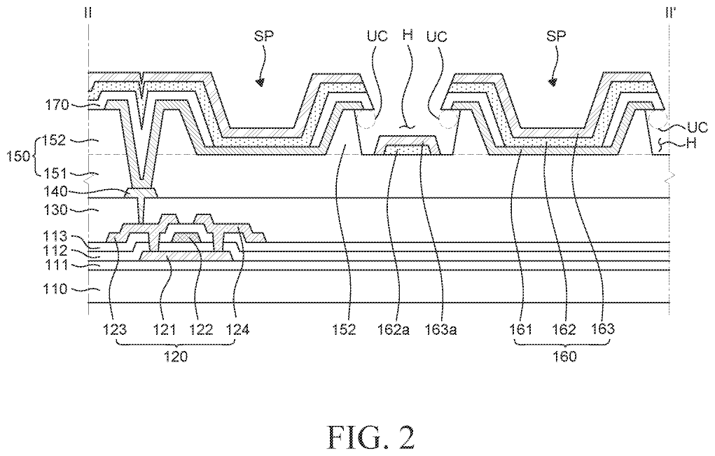

FIG. 1 is a plan view of a display device according to an exemplary embodiment of the present disclosure. FIG. 2 is a cross-sectional view of the display device taken along II-II′ of FIG. 1.

Referring to FIGS. 1 and 2, a display device 100 includes a substrate 110, transistors 120, a first overcoating layer 130, an auxiliary electrode 140, a second overcoating layer 150, light emitting elements 160, and banks 170. The display device 100 can be implemented as a top emission type display device, but is not limited thereto.

The substrate 110 is a substrate for supporting and protecting various components of the display device 100. The substrate 110 can be formed of glass or a plastic material having flexibility. When the substrate 110 is formed of a plastic material, it can be formed of, for example, polyimide (PI). However, the present disclosure is not limited thereto.

The substrate 110 includes an active area A/A and a non-active area N/A.

The active area A/A is an area in which an image is displayed in the display device 100, and display element(s) and various driving elements for driving the display elements can be disposed in the active area A/A. For example, the display element can be configured as the light emitting element 160 including a first electrode 161, an organic layer 162, and a second electrode 163. In addition, various driving elements for driving the display element, such as the transistor 120, a capacitor, and lines can be disposed in the active area A/A.

A plurality of sub-pixels SP can be included in the active area A/A. The sub-pixels SP are minimum units constituting a screen, and each of the plurality of sub-pixels SP can include the light emitting element 160 and a driving circuit.

Each of the plurality of sub-pixels SP can emit light of different wavelengths. For example, the plurality of sub-pixels SP can include a red sub-pixel, a green sub-pixel, and a blue sub-pixel. In addition, the plurality of sub-pixels SP can further include a white sub-pixel.

The driving circuit of the sub-pixel SP is a circuit for controlling driving of the light emitting element 160. For example, the driving circuit can be configured to include the transistor 120 and a capacitor, but is not limited thereto.

The non-active area N/A is an area in which an image is not displayed, and various components for driving the plurality of sub-pixels SP disposed in the active area A/A can be disposed in the non-active area N/A. For example, a driver IC (integrated circuit), a flexible film, and the like that supply signals for driving the plurality of sub-pixels SP can be disposed.

The non-active area N/A can be an area surrounding the active area A/A as shown in FIG. 1. However, the present disclosure is not limited thereto. For example, the non-active area N/A can be an area extending from the active area A/A.

Hereinafter, the plurality of sub-pixels SP disposed in the active area A/A will be described in more detail with reference to FIG. 2.

Referring to FIG. 2, a buffer layer 111 is disposed on the substrate 110. The buffer layer 111 can serve to improve adhesion between layers formed on the buffer layer 111 and the substrate 110, and to block alkali components or the like leaking from the substrate 110. The buffer layer 111 can be formed of a single layer of silicon nitride (SiNx) or silicon oxide (SiOx), or multilayers of silicon nitride (SiNx) or silicon oxide (SiOx), but is not limited thereto. The buffer layer 111 is not an essential component and can be omitted based on a type and a material of the substrate 110, a structure and a type of the transistor 120, and the like.

The transistor 120 is disposed on the buffer layer 111. The transistor 120 can be used as a driving element for driving the light emitting element 160 of the active area A/A. The transistor 120 includes an active layer 121, a gate electrode 122, a source electrode 123, and a drain electrode 124. The transistor 120 illustrated in FIG. 2 is a driving transistor and is a thin film transistor having a top gate structure in which the gate electrode 122 is disposed on the active layer 121. However, the present disclosure is not limited thereto, and the transistor 120 can be implemented as a transistor having a bottom gate structure.

The active layer 121 is disposed on the buffer layer 111. The active layer 121 is an area in which a channel is formed when the transistor 120 is driven. The active layer 121 can be formed of an oxide semiconductor, or can be formed of amorphous silicon (a-Si), polycrystalline silicon (poly-Si), or an organic semiconductor.

A gate insulating layer 112 is disposed on the active layer 121. The gate insulating layer 112 is a layer for electrically insulating the active layer 121 and the gate electrode 122 and can be formed of an insulating material. For example, the gate insulating layer 112 can be formed of a single layer of silicon nitride (SiNx) or silicon oxide (SiOx), which is an inorganic material, or multilayers of silicon nitride (SiNx) or silicon oxide (SiOx), but is not limited thereto.

In the gate insulating layer 112, contact holes through which the source electrode 123 and the drain electrode 124 contact a source region and a drain region of the active layer 121, respectively, are formed. The gate insulating layer 112 can be formed over an entire surface of the substrate 110 as shown in FIG. 2, or can be patterned to have the same width as the gate electrode 122, but is not limited thereto.

The gate electrode 122 is disposed on the gate insulating layer 112. The gate electrode 122 is disposed on the gate insulating layer 112 to overlap a channel region of the active layer 121. The gate electrode 122 can be formed of any one of various metallic materials, for example, molybdenum (Mo), aluminum (Al), chrome (Cr), gold (Au), titanium (Ti), nickel (Ni), neodymium (Nd), and copper (Cu) or an alloy of two or more of them, or a multiple layer thereof, but is not limited thereto.

An interlayer insulating layer 113 is disposed on the gate electrode 122. The interlayer insulating layer 113 can be formed of a single layer of silicon nitride (SiNx) or silicon oxide (SiOx), which is an inorganic material, or multilayers of silicon nitride (SiNx) or silicon oxide (SiOx), but is not limited thereto. In the interlayer insulating layer 113, contact holes through which the source electrode 123 and the drain electrode 124 contact the source region and the drain region of the active layer 121, respectively, are formed.

The source electrode 123 and the drain electrode 124 are disposed on the interlayer insulating layer 113. The source electrode 123 and the drain electrode 124 are spaced apart from each other on the same layer. The source electrode 123 and the drain electrode 124 are electrically connected to the active layer 121 through the contact holes of the gate insulating layer 112 and the interlayer insulating layer 113. The source electrode 123 and the drain electrode 124 can be formed of any one of various metallic materials, for example, molybdenum (Mo), aluminum (Al), chrome (Cr), gold (Au), titanium (Ti), nickel (Ni), neodymium (Nd), and copper (Cu) or an alloy of two or more of them, or a multiple layer thereof, but is not limited thereto.

In FIG. 2, the driving transistor among various types of transistors 120 included in the display device 100 is illustrated, but other transistors such as a switching transistor and the like can also be disposed.

The first overcoating layer 130 is disposed on the interlayer insulating layer 113 and the transistor 120. The first overcoating layer 130 is an insulating layer for protecting the transistor 120 and planarizing an upper portion of the transistor 120. A contact hole for exposing the source electrode 123 of the transistor 120 is formed in the first overcoating layer 130. Although it is illustrated in FIG. 2 that a contact hole for exposing the source electrode 123 is formed in the first overcoating layer 130, the present disclosure is not limited thereto. For example, a contact hole for exposing the drain electrode 124 can be formed in the first overcoating layer 130.

The first overcoating layer 130 can be formed of one of an acrylic resin, an epoxy resin, a phenol resin, a polyamide-based resin, a polyimide-based resin, an unsaturated polyester-based resin, a polyphenylene-based resin, a polyphenylene sulfide-based resin, benzocyclobutene, and a photoresist, but is not limited thereto.

Meanwhile, a passivation layer covering the interlayer insulating layer 113 and the transistor 120 can be further disposed under the first overcoating layer 130. The passivation layer can be formed of a single layer of silicon nitride (SiNx) or silicon oxide (SiOx), or multilayers of silicon nitride (SiNx) or silicon oxide (SiOx), but is not limited thereto.

The auxiliary electrode 140 is disposed on the first overcoating layer 130. The auxiliary electrode 140 can serve to electrically connect the transistor 120 and the light emitting element 160. The auxiliary electrode 140 is electrically connected to the source electrode 123 of the transistor 120 through the contact hole formed in the first overcoating layer 130. The auxiliary electrode 140 can be formed as a single layer or multiple layers formed of any one of molybdenum (Mo), copper (Cu), titanium (Ti), aluminum (Al) chromium (Cr), gold (Au), nickel (Ni), and neodymium (Nd) or alloys of them.

The second overcoating layer 150 is disposed on the first overcoating layer 130. The second overcoating layer 150 is an insulating layer for planarizing upper portions of the first overcoating layer 130 and the auxiliary electrode 140. A contact hole for exposing the auxiliary electrode 140 is formed in the second overcoating layer 150.

The second overcoating layer 150 can be formed of one of an acrylic resin, an epoxy resin, a phenol resin, a polyamide-based resin, a polyimide-based resin, an unsaturated polyester-based resin, a polyphenylene-based resin, a polyphenylene sulfide-based resin, benzocyclobutene, and a photoresist, but is not limited thereto.

The second overcoating layer 150 includes a base portion 151 and a plurality of protrusions 152. The base portion 151 and the plurality of protrusions 152 can be integrally formed as shown in FIG. 2. For example, the base portion 151 and the plurality of protrusions 152 can be formed of the same material and can be simultaneously formed through the same process, for example, a mask process, but is not limited thereto.

The base portion 151 is disposed on the first overcoating layer 130. An upper surface of the base portion 151 has a surface parallel to the substrate 110. Accordingly, the base portion 151 can planarize a step that can occur due to components disposed thereunder.

The plurality of protrusions 152 are disposed on the base portion 151. The plurality of protrusions 152 are integrally formed with the base portion 151 and have a shape protruding from the base portion 151. The plurality of protrusions 152 can have a shape in which an upper surface thereof is smaller than a lower surface thereof, but is not limited thereto.

Each of the plurality of protrusions 152 includes the upper surface and side surfaces. The upper surface of the protrusion 152 is a surface positioned at an uppermost portion of the protrusion 152 and can be a surface substantially parallel to the base portion 151 or the substrate 110. The side surfaces of the protrusion 152 can be surfaces connecting the upper surface of the protrusion 152 and the base portion 151. The side surface of the protrusion 152 can have a shape inclined toward the base portion 151 from the upper surface thereof.

A part of the plurality of protrusions 152 can include a groove H. In particular, the groove H can be disposed between the plurality of sub-pixels SP. The groove H can be formed in an inverted spacer shape in which a width thereof is reduced downwardly. The upper surface of the base portion 151 can be exposed by the groove H, but is not limited thereto. However, it is preferable that the groove H is not formed up to an inside of the base portion 151. If the groove H is disposed up to a partial area of the base portion 151, interference can occur in a line under the base portion 151 depending on a design of the display device 100, which is not preferable.

The groove H can be formed by etching a portion of the protrusion 152 using the first electrode 161 and the bank 170 as a mask. The groove H can include an undercut area UC under the first electrode 161 and the bank 170. The undercut area UC can be an area formed by etching a material of the protrusion 152 to lower portions of the first electrode 161 and the bank 170. For example, the groove H can be formed so that the side surface of the protrusion 152 enters more inwardly than ends of the first electrode 161 and the bank 170. Accordingly, the organic layer 162 and the second electrode 163 can be formed to have a disconnected structure in an area corresponding to the groove H.

The light emitting element 160 is disposed on the second overcoating layer 150. The light emitting element 160 includes the first electrode 161 electrically connected to the source electrode 123 of the transistor 120, the organic layer 162 disposed on the first electrode 161, and the second electrode 163 formed on the organic layer 162.

The first electrode 161 is disposed to correspond to each of the plurality of sub-pixels SP. The first electrodes 161 are disposed to cover the base portion 151 and the plurality of protrusions 152. Specifically, the first electrodes 161 can be disposed on the upper surface of the base portion 151 on which the protrusions 152 are not disposed and on the side surfaces of the plurality of protrusions 152. For example, the first electrodes 161 are disposed along shapes of the base portion 151 and the protrusions 152. Also, the first electrodes 161 can be formed on partial areas of the upper surfaces of the plurality of protrusions 152.

The first electrode 161 can be an anode of the light emitting element 160. The first electrode 161 is electrically connected to the auxiliary electrode 140 through the contact hole formed in the second overcoating layer 150. The first electrode 161 can be electrically connected to the source electrode 123 of the transistor 120 through the auxiliary electrode 140. However, the first electrode 161 can be configured to be electrically connected to the drain electrode 124 of the transistor 120 depending on the type of the transistor 120 and a design method of the driving circuit.

Although the first electrode 161 is illustrated as a single layer in FIG. 2, the first electrode 161 can be configured as a multilayer. For example, the first electrode 161 can include a reflective layer for reflecting light emitted from the organic layer 162 toward the second electrode 163 and a transparent conductive layer for supplying holes to the organic layer 162.

The reflective layer can be disposed on the second overcoating layer 150 and reflect light emitted from the light emitting element 160 upwardly. The light generated in the organic layer 162 of the light emitting element 160 may not be emitted only upwardly, but can also be emitted laterally. The laterally emitted light can be directed into the display device 100, and can be trapped inside the display device 100 due to total reflection, and further can disappear while traveling in an inward direction of the display device 100. Accordingly, the reflective layer is disposed under the organic layer 162 to cover side portions of the plurality of protrusions 152, and can change a traveling direction of light traveling toward a side portion of the organic layer 162 to a front direction.

The reflective layer can be formed of a metallic material, for example, can be formed of a metallic material such as aluminum (Al), silver (Ag), copper (Cu), magnesium-silver alloy (Mg:Ag) or the like, but is limited thereto.

The transparent conductive layer is disposed on the reflective layer. The transparent conductive layer can be formed of a conductive material having a high work function in order to supply holes to the organic layer 162. For example, the transparent conductive layer can be formed of indium tin oxide (ITO), indium zinc oxide (IZO), indium tin zinc oxide (ITZO), zinc oxide (ZnO), and tin oxide (TO)-based transparent conductive oxides, but is not limited thereto.

The ends of the first electrode 161 can overlap the groove H. In other words, the first electrode 161 can protrude to cover the groove H on an extension line of the upper surface of the protrusion 152. The first electrode 161 can be deposited on a partial area of the upper surface of the protrusion 152. Thereafter, a portion of the protrusion 152 can be etched using the first electrode 161 as a mask, so that the groove H can be formed. Accordingly, the first electrode 161 may not be disposed in the groove H, but can overlap the groove H at an outside of the groove H.

The bank 170 is disposed on the second overcoating layer 150 and the first electrode 161. The bank 170 can cover a portion of the first electrode 161 and define an emission area and a non-emission area. The emission area can mean an area in which light is substantially generated by the organic layer 162 in each of the plurality of sub-pixels SP. The bank 170 is not disposed in the emission area, and the organic layer 162 is directly positioned on the first electrode 161 to generate light. The non-emission area can mean an area in which light is not generated. However, the non-emission area does not allow light to be generated therefrom but can have a light reflection area that reflects light such that light is extracted to the front. The light reflection area can correspond to an area corresponding to an inclined surface that is the side surface of the protrusion 152. In the light reflection area, the light emitted laterally from the light emitting element 160 by the first electrode 161 that is disposed along the inclined surface of the protrusion 152 can be extracted to the front. Also, an area corresponding to the groove H in which the bank 170 is not disposed at all between the plurality of sub-pixels SP can also correspond to the non-emission area.

Meanwhile, the first electrode 161 can be divided into a first area, a second area, and a third area according to the emission area, the non-emission area, and the light reflection area. For example, the first area of the first electrode 161 can correspond to the emission area and contribute to light emission. The second area of the first electrode 161 can be disposed along the inclined surface of the protrusion 152 and contribute to light reflection. The third area of the first electrode 161 can be disposed to cover the upper surface of the protrusion 152 and the groove H on the extension line of the upper surface of the protrusion 152. The first area, the second area, and the third area of the first electrode 161 can be deposited in one configuration through the same process.

The end of the bank 170 can overlap the groove H. In other words, the bank 170 can extend to cover a side surface of the first electrode 161 corresponding to the groove H from an upper surface of the first electrode 161. Accordingly, the bank 170 can protrude to cover the groove H on the extension line of the upper surface of the protrusion 152 or an extension line of the upper surface of the first electrode 161. The bank 170 can be deposited to cover the first electrode 161 on the upper surface of the protrusion 152. Thereafter, a portion of the protrusion 152 can be etched using the first electrode 161 and the bank 170 as a mask, so that the groove H can be formed. Accordingly, the bank 170 may not be disposed in the groove H, and can overlap the groove H at the outside of the groove H.

The bank 170 can be formed of an inorganic material. For example, the bank 170 can be formed of a single layer of silicon nitride (SiNx) or silicon oxide (SiOx), or multiple layers of silicon nitride (SiNx) or silicon oxide (SiOx).

Both the first electrode 161 and the bank 170 can be formed of an inorganic material, and the plurality of protrusions 152 can be formed of an organic material. Accordingly, when the plurality of protrusions 152 are etched, the first electrode 161 and the bank 170 are not removed, and only the plurality of protrusions 152 can be easily removed. In particular, dry etch using oxygen (02) can be used in etching the plurality of protrusions 152. Accordingly, only the organic material constituting the plurality of protrusions 152 can be selectively etched, so that the groove H can be formed. In this case, the groove H can be formed so that an inner side surface thereof enters more inwardly than the ends of the first electrode 161 and the bank 170. For example, the undercut area UC can be formed under the first electrode 161 and the bank 170. Due to the undercut area UC, a lower surface of the first electrode 161 and a lower surface of the bank 170 can be exposed by the groove H.

In the area corresponding to the groove H, the banks 170 respectively disposed in the sub-pixels SP adjacent to each other can be spaced apart from each other. Also, in the area corresponding to the groove H, the first electrodes 161 respectively disposed in the sub-pixels SP adjacent to each other can be spaced apart from each other. A distance between the bank 170 disposed over one side of the groove H and the bank 170 disposed over the other side of the groove H can be smaller than the width of the groove H. Also, a distance between the first electrode 161 disposed over one side of the groove H and the first electrode 161 disposed over the other side of the groove H can be smaller than the width of the groove H. Here, the width of the groove H can be a concept including all inner widths of the groove H between a maximum width corresponding to an entrance of the groove H and a minimum width corresponding to a bottom surface of the groove H.

As the first electrode 161 and the bank 170 protrude than the inner side surface of the groove H so as to overlap the groove H, the organic layer 162 and the second electrode 163 disposed on the first electrode 161 can have a disconnected structure. For example, it can be difficult to deposit the organic layer 162 and the second electrode 163 in the undercut area UC under the first electrode 161 and the bank 170 due to a shadow effect. Accordingly, the organic layers 162 and the second electrodes 163 of the adjacent sub-pixels SP in at least a partial area between the plurality of sub-pixels SP can be electrically insulated from each other.

The organic layer 162 is disposed on the first electrode 161 and the bank 170. For example, the organic layer 162 is disposed on the first electrode 161 in the light emitting area and is disposed on the bank 170 in the non-emission area. The organic layer 162 can be disposed along shapes of the first electrode 161 and the bank 170. The organic layer 162 includes an emission layer and a common layer.

The emission layer is an organic layer for emitting light of a specific color. Different emission layers can be disposed in each of the plurality of sub-pixels SP, or the same emission layer can be disposed in an entirety of the plurality of sub-pixels SP. For example, when different emission layers are disposed in each of the plurality of sub-pixels SP, a red emission layer can be disposed in the red sub-pixel, a green emission layer can be disposed in the green sub-pixel, and a blue emission layer can be disposed in the blue sub-pixel. When the emission layer is formed as the same layer over the plurality of sub-pixels SP, light from the emission layer can be converted into light of various colors through a separate light conversion layer, a color filter, and the like.

The common layer is an organic layer disposed to improve luminous efficiency of the emission layer. The common layer can be formed as the same layer over the plurality of sub-pixels SP. For example, the common layer of each of the plurality of sub-pixels SP can be simultaneously formed of the same material and through the same process. The common layer can include a hole injection layer, a hole transport layer, an electron transport layer, an electron injection layer, and a charge generation layer, but is not limited thereto.

The second electrode 163 is disposed on the organic layer 162. The second electrode 163 can be disposed along the shape of the organic layer 162. Since the second electrode 163 supplies electrons to the organic layer 162, it can be formed of a conductive material having a low work function. The second electrode 163 can be a cathode of the light emitting element 160. The second electrode 163 can be formed of a transparent conductive material such as indium tin oxide (ITO) or indium zinc oxide (IZO), or a metal alloy such as MgAg or an ytterbium (Yb) alloy, and can further include a metal doped layer, but is not limited thereto. Meanwhile, the second electrode 163 can be electrically connected to a low potential power line and receive a low potential power signal.

Further, in the groove H, a dummy organic layer 162a and a dummy conductive layer 163a are disposed. The dummy organic layer 162a can be a layer that is discontinued or disconnected from the organic layer 162 when depositing the organic layer 162, and that is disposed on the bottom surface of the groove H. The dummy conductive layer 163a can be a layer that is discontinued or disconnected from the second electrode 163 when depositing the second electrode 163, and that is disposed on the bottom surface of the groove H. The dummy organic layer 162a can be spaced apart from the organic layer 162 of each of the sub-pixels SP between the plurality of sub-pixels SP. The dummy conductive layer 163a can be spaced apart from the second electrode 163 of each of the sub-pixels SP between the plurality of sub-pixels SP.

The organic layer 162 and the second electrode 163 can have a disconnected structure between the plurality of sub-pixels SP. For example, in the area corresponding to the groove H, the organic layer 162 of the sub-pixel SP disposed over one side of the groove H, the dummy organic layer 162a disposed on the bottom surface of the groove H, and the organic layer 162 of the sub-pixel SP disposed over the other side of the groove H can be formed to be disconnected without being continuous. Accordingly, the organic layers 162 of the respective sub-pixels SP adjacent to each other can be electrically insulated from each other.

In addition, in the area corresponding to the groove H, the second electrode 163 of the sub-pixel SP disposed over one side of the groove H, the dummy conductive layer 163a disposed on the bottom surface of the groove H, and the second electrode 163 of the sub-pixel SP disposed over the other side of the groove H can be formed to be disconnected without being continuous. Accordingly, the second electrodes 163 of the respective sub-pixels SP adjacent to each other can be electrically insulated from each other. Here, when different emission layers are deposited on each of the plurality of sub-pixels SP, the disconnected organic layer 162 can include only the common layer. If the same emission layer is deposited on the entirety of the plurality of sub-pixels SP, the disconnected organic layer 162 can include both the emission layer and the common layer.

Specifically, the end of the first electrode 161 and the end of the bank 170 protrude to overlap the groove H, so that the undercut area UC can be formed under the first electrode 161 and the bank 170. Accordingly, in a deposition process of the organic layer 162 and the second electrode 163, it can be difficult to deposit the organic layer 162 and the second electrode 163 in the undercut area UC due to a shadow effect. For example, the organic layer 162 and the second electrode 163 are not deposited in an area covered by the first electrode 161 and the bank 170 among inner surfaces of the groove H. In other words, the organic layer 162 and the second electrode 163 are not deposited on the lower surface of the first electrode 161 overlapping the groove H, the lower surface of the bank 170 overlapping the groove H, a side surface of the groove H, and the bottom surface of the groove H facing the first electrode 161 and the bank 170. Accordingly, the organic layer 162 and the second electrode 163 can have a disconnected structure between the plurality of sub-pixels SP. As such, a current leakage phenomenon in which a current of a specific sub-pixel SP flows to a sub-pixel SP adjacent thereto can be minimized.

Meanwhile, the grooves H can be configured to surround each of the plurality of sub-pixels SP. However, the grooves H do not completely surround the plurality of sub-pixels SP, and only the protrusions 152 can exist without the grooves H in some areas. For example, in some areas, some of the banks 170, the organic layers 162, and the second electrodes 163 of the respective sub-pixels SP adjacent to each other can be connected. If the grooves H completely surround each of the plurality of sub-pixels SP, the organic layers 162 and/or the cathodes 163 are completely separated in each of the sub-pixels SP, and thus, it can be difficult for the plurality of light emitting elements 160 to emit light. Accordingly, the grooves H can be formed an open curve surrounding each of the plurality of light emitting elements 160.

Alternatively, the groove H can be disposed only between the sub-pixels SP that emit light of different colors. For example, between the red sub-pixels, between the green sub-pixels, and between the blue sub-pixels, a groove is not disposed and the organic layer 162 and the second electrode 163 can be continuously formed. In addition, between the red sub-pixel and the green sub-pixel, between the red sub-pixel and the blue sub-pixel, and between the green sub-pixel and the blue sub-pixel, a groove is formed, and the organic layer 162 and the second electrode 163 can have a disconnected structure. However, the present disclosure is not limited thereto, and the disconnected structure of the organic layer 162 and the second electrode 163 and the groove H can be formed in any region, as long as the region is for preventing leakage current.

Meanwhile, an encapsulation unit can be formed on the light emitting element 160 to protect the light emitting element 160, which is vulnerable to moisture, from being exposed to moisture. The encapsulation unit can block oxygen and moisture from penetrating into the display device 100 from the outside. The encapsulation unit can have a structure in which an inorganic layer and an organic layer are alternately stacked, but is not limited thereto.

In general, a common layer among organic layers of a plurality of light emitting elements is formed as one layer over an entirety of a plurality of sub-pixels. As light emitting elements of the plurality of sub-pixels are formed in a structure that shares a common layer, when the light emitting element of a specific sub-pixel emits light, a current leakage phenomenon in which a current flows to the light emitting element of the sub-pixel adjacent to the specific sub-pixel can occur. For example, when only a red sub-pixel among the plurality of sub-pixels emits light, a portion of a current supplied to drive the light emitting element of the red sub-pixel can leak to a green sub-pixel and a blue sub-pixel that are adjacent to the red sub-pixel through the common layer. For example, the light emitting elements of other unintentional sub-pixels emit light due to the current leakage phenomenon, causing color mixing between the plurality of sub-pixels, and increasing power consumption. In addition, color abnormality and visible spot can be visually recognized due to a leakage current, and thus, display quality can be degraded.

In addition, when the emission layers are separately disposed in each of the plurality of sub-pixels, the respective emission layers have different turn-on voltages from each other. For example, the turn-on voltage for driving the blue sub-pixel on which the blue emission layer is disposed can be the highest, and the turn-on voltage for driving the red sub-pixel on which the red emission layer is disposed can be the lowest. In addition, since a barrier through which a current can flow is lower in the red sub-pixel or the green sub-pixel in which the turn-on voltage is low, than in the blue sub-pixel in which the turn-on voltage is the highest, the current leaked through the common layer can easily flow from the blue sub-pixel in which the turn-on voltage is the highest to the green sub-pixel or the red sub-pixel in which the turn-on voltage is low. Accordingly, when the blue sub-pixel is driven, the red sub-pixel and the green sub-pixel in which the turn-on voltage is low can emit light together.

In particular, during low grayscale driving, a luminance of light that is emitted from the driven sub-pixel SP is low, so that light emitted from adjacent sub-pixels SP can be more easily recognized. For example, during low grayscale driving, color abnormality and visible spot due to a leakage current can be more easily recognized, and thus display quality can be seriously degraded. In addition, when low grayscale white light is displayed, the red sub-pixel having the lowest turn-on voltage through the common layer first emits light, so that a reddish phenomenon in which white with red light is displayed instead of pure white can occur.

Accordingly, in the display device 100 according to the present disclosure, since the organic layer 162 has a disconnected structure between the plurality of sub-pixels SP, a leakage current through the common layer can be minimized. Specifically, the groove H is formed in a portion of the protrusions 152 between the plurality of sub-pixels SP, and the end of the first electrode 161 and the end of the bank 170 can be disposed to overlap the groove H. In this case, the first electrodes 161 and the banks 170 of the respective sub-pixels SP adjacent in the area corresponding to the groove H are spaced apart from each other. Accordingly, when the organic layer 162 is deposited on the first electrode 161 and the bank 170, the organic layer 162 can be deposited to be discontinuous without being continuous between the adjacent sub-pixels SP. For example, in the area corresponding to the groove H, the organic layer 162 can be deposited up to the end of the bank 170 overlapping the groove H, and the dummy organic layer 162a can be deposited on the bottom surface of the groove H. Here, the organic layers 162 of the respective sub-pixels SP adjacent to each other can be spaced apart from each other. Also, the organic layer 162 on the protrusion 152 and the dummy organic layer 162a on the base portion 151 can be spaced apart from each other. Accordingly, a flow of the leakage current through the common layer of the organic layer 162 can be reduced.

In addition, not only the organic layer 162 but also the second electrode 163 on the organic layer 162 can be formed to have a disconnected structure. For example, the second electrode 163 can be deposited to be discontinuous in a partial area between the adjacent sub-pixels SP. Specifically, in the area corresponding to the groove H, the second electrode 163 can be deposited up to the end of the organic layer 162 overlapping the groove H, and the dummy conductive layer 163a can be deposited on the bottom surface of the groove H. Here, the second electrodes 163 of the respective sub-pixels SP adjacent to each other can be spaced apart from each other. Also, the second electrode 163 on the protrusion 152 and the dummy conductive layer 163a on the base portion 151 can be spaced apart from each other. Accordingly, a current leakage phenomenon that can occur through the second electrode 163 can be minimized.

For example, the common layers and the second electrodes 163 of the respective sub-pixels SP adjacent to each other in at least some areas of the protrusions 152 between the plurality of sub-pixels SP can have a structure in which they are spaced apart from each other. For example, a path through which the leakage current flows can be disconnected, and thus, the path through which the leakage current flows to the adjacent sub-pixel SP can be blocked. Accordingly, a phenomenon in which when one sub-pixel SP is driven, a leakage current flows to a sub-pixel SP adjacent to the one sub-pixel SP, so that an occurrence of an unintended sub-pixel SP emitting light can be minimized. In addition, it is possible to minimize a defect in which visible spot is recognized and the color gamut is lowered by color mixing due to a leakage current, and display quality can be improved.

In the display device 100 according to the present disclosure, the first electrode 161 and the bank 170 can be formed of an inorganic material, and the protrusion 152 of the second overcoating layer 150 can be formed of an organic material. Accordingly, when a portion of the protrusion 152 is etched using the first electrode 161 and the bank 170 as a mask, only the protrusion 152 can be easily removed, so that the groove H can be formed. In addition, since the first electrode 161 and the bank 170 are used as a mask, the protrusion 152 can be etched to form the undercut area UC under the first electrode 161 and the bank 170 when the groove H is formed. Accordingly, when the organic layer 162 and the second electrode 163 are deposited on the bank 170, the disconnected structure of the organic layer 162 and the second electrode 163 can be more easily formed by the undercut area UC.

In the area overlapping the groove H, the bank 170 can be formed to cover the side surface of the first electrode 161. Accordingly, a short circuit between the second electrode 163 and the first electrode 161 can be prevented. Although the second electrode 163 is illustrated to be disposed only on an upper surface of the organic layer 162 in FIG. 2, the second electrode 163 can also be disposed on a portion of a side surface of the organic layer 162 and a side surface of the bank 170. Specifically, the second electrode 163 can be formed of a material having superior step coverage compared to the organic layer 162. Accordingly, while the organic layer 162 is deposited only on an upper surface of the bank 170, the second electrode 163 can be deposited not only on the upper surface of the organic layer 162, but also deposited on the side surface of the organic layer 162 and the side surface of the bank 170. In this case, when the bank 170 does not cover the side surface of the first electrode 161, the second electrode 163 is deposited up to the side surface of the first electrode 161, and a short circuit can occur between the first electrode 161 and the second electrode 163.

Accordingly, in the present disclosure, the bank 170 is disposed to cover the side surface of the first electrode 161 to prevent the first electrode 161 and the second electrode 163 from contacting each other, and defects of the display device 100 can be prevented.

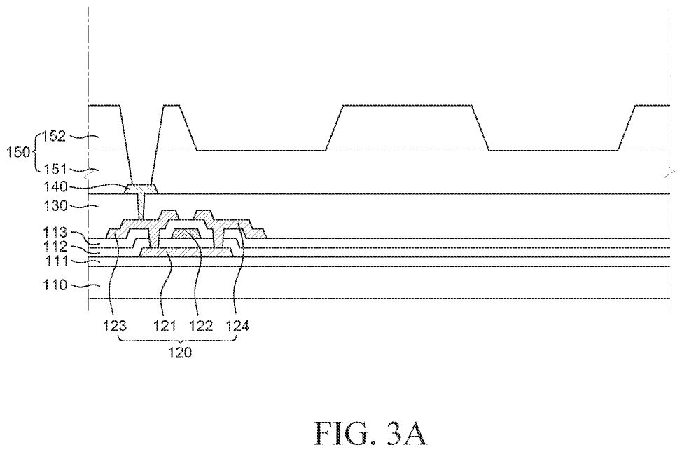

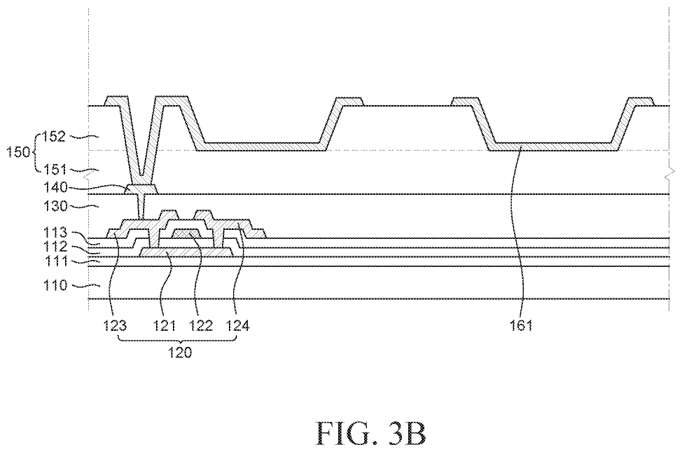

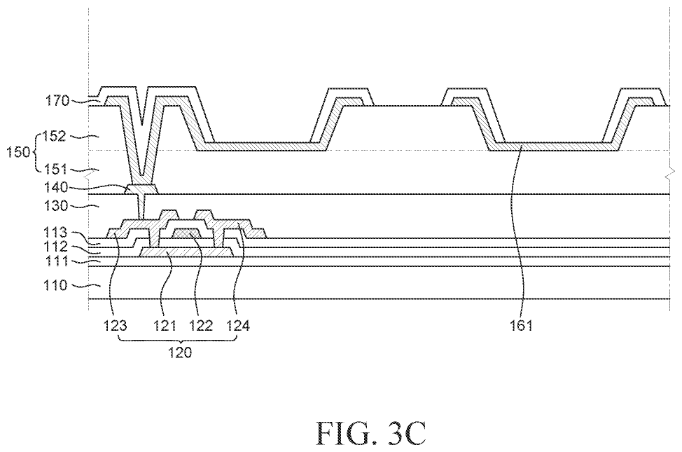

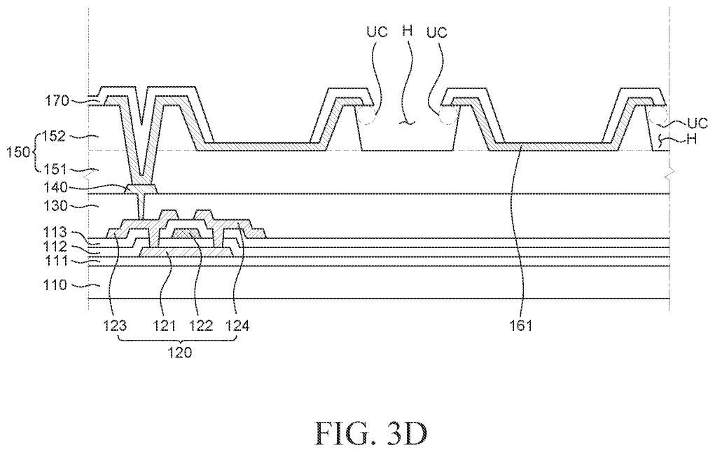

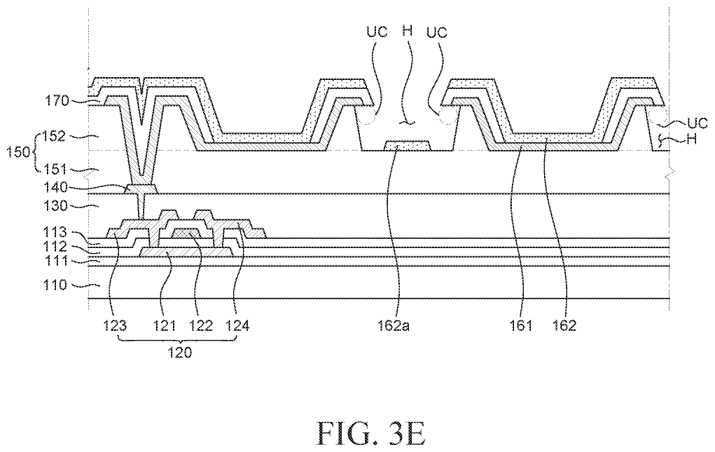

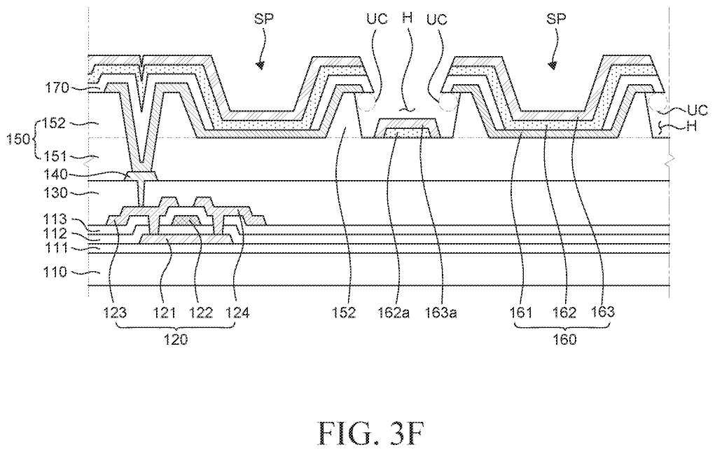

FIGS. 3A to 3F are cross-sectional views sequentially illustrating a method of manufacturing a display device according to an exemplary embodiment of the present disclosure.

Referring to FIG. 3A, the buffer layer 111, the transistor 120, the gate insulating layer 112, the interlayer insulating layer 113, the first overcoating layer 130, the auxiliary electrode 140, and the second overcoating layer 150 are formed. In this case, the second overcoating layer 150 includes the base portion 151 and the plurality of protrusions 152 protruding from the base portion 151. The base portion 151 can correspond to an area in which the light emitting element 160 is to be disposed in each of the plurality of sub-pixels SP. The plurality of protrusions 152 can correspond to non-emission areas between the light emitting elements 160. In addition, a contact hole for exposing the auxiliary electrode 140 can be formed in a partial area of the plurality of protrusions 152 corresponding to the auxiliary electrode 140.

The second overcoating layer 150 can be formed of an organic material. Specifically, the second overcoating layer 150 can be formed of one of an acrylic resin, an epoxy resin, a phenol resin, a polyamide-based resin, a polyimide-based resin, an unsaturated polyester-based resin, a polyphenylene-based resin, a polyphenylene sulfide-based resin, benzocyclobutene, and a photoresist, but is not limited thereto.

Referring to FIG. 3B, the first electrode 161 is disposed on a partial area of the second overcoating layer 150. The first electrode 161 can be patterned to correspond to each of the plurality of sub-pixels SP. For example, the first electrodes 161 disposed in each of the plurality of sub-pixels SP can be spaced apart from each other. The first electrodes 161 can be disposed to cover the base portion 151 and the plurality of protrusions 152. In particular, the first electrodes 161 can be disposed to cover side surfaces of the plurality of protrusions 152 extending from the upper surface of the base portion 151. Accordingly, light extraction efficiency can be improved by changing a traveling direction of light emitted from the light emitting element 160 to the front direction.

The first electrode 161 can include a reflective layer and a transparent conductive layer. The reflective layer can be formed of a metallic material, for example, can be formed of a metallic material such as aluminum (Al), silver (Ag), copper (Cu), magnesium-silver alloy (Mg:Ag), or the like, but is limited thereto. The transparent conductive layer can be formed of indium tin oxide (ITO), indium zinc oxide (IZO), indium tin zinc oxide (ITZO), zinc oxide (ZnO), and tin oxide (TO)-based transparent conductive oxides, but is not limited thereto.

Referring to FIG. 3C, the bank 170 is disposed on a portion of the first electrode 161. The bank 170 can be disposed to expose the first electrode 161 disposed on the upper surface of the base portion 151. Also, the banks 170 can be disposed to cover the first electrodes 161 disposed on the plurality of protrusions 152. In particular, the banks 170 can be disposed on the plurality of protrusions 152 to cover the ends of the first electrodes 161. For example, the bank 170 can cover the side surface of the first electrode 161 and thus, prevent the first electrode 161 from being electrically connected to other components.

Meanwhile, the banks 170 can be disposed to expose partial areas of the upper surfaces of the plurality of protrusions 152. Specifically, the bank 170 can expose a portion of the protrusion 152 corresponding to the non-emission area between the plurality of sub-pixels SP. Accordingly, the bank 170 may not be entirely disposed on the substrate 110, but can have a disconnected structure in a partial area between the plurality of sub-pixels SP.

The bank 170 can be formed of an inorganic material. For example, the bank 170 can be formed of a single layer of silicon nitride (SiNx) or silicon oxide (SiOx), or multiple layers of silicon nitride (SiNx) or silicon oxide (SiOx).

Referring to FIG. 3D, some of the plurality of protrusions 152 exposed by the banks 170 are etched to form the grooves H. For example, the grooves H can be formed in partial areas of the plurality of protrusions 152. The groove H can be disposed between the plurality of sub-pixels SP. The groove H can be formed to expose the upper surface of the base portion 151, but is not limited thereto.

The groove H can be formed through dry etch using oxygen. When such an etching method is used, only an organic material can be selectively removed. For example, a partial area of the protrusion 152 formed of an organic material can be removed by using the first electrode 161 and the bank 170 formed of an inorganic material as a mask. In particular, the material forming the protrusion 152 can be etched until the respective lower surfaces of the end of the first electrode 161 and the end of the bank 170 are exposed. For example, due to a material difference between the first electrode 161 and the bank 170 which are formed of an inorganic material, and the protrusion 152 which is formed of an organic material, the material constituting the protrusion 152 can be etched more inwardly than the ends of the first electrode 161 and the bank 170. Accordingly, the first electrode 161 and the bank 170 have a structure protruding from the upper surface of the protrusion 152 to overlap the groove H. In addition, the undercut area UC can be formed under the first electrode 161 and the bank 170. Accordingly, the organic layer 162 and the second electrode 163 that are subsequently deposited are not deposited in the undercut area UC covered by the first electrode 161 and the bank 170. As such, the organic layer 162 and the second electrode 163 can have a disconnected structure.

Referring to FIG. 3E, the organic layer 162 is formed on the first electrode 161 and the bank 170. The organic layers 162 of the respective sub-pixels SP adjacent to each other can be spaced apart from each other. Specifically, in the area corresponding to the groove H, the banks 170 of the respective sub-pixels SP adjacent to each other can be spaced apart from each other, and the undercut area UC can be formed under the bank 170. Accordingly, the organic layer 162 can be disposed only on the first electrode 161 and the bank 170, and may not be formed in the undercut area UC covered by the first electrode 161 and the bank 170. For example, the organic layer 162 is not deposited on the side surface of the groove H and the bottom surface of the groove H facing the first electrode 161 and the bank 170.

The dummy organic layer 162a can be deposited on an area of the bottom surface of the groove H that is not covered by the first electrode 161 and the bank 170. The dummy organic layer 162a can be formed on the same layer as the first electrode 161 in the emission area. The dummy organic layer 162a is a layer that is simultaneously formed of the same material as the organic layer 162. For example, when different emission layers are deposited on each of the plurality of sub-pixels SP, the dummy organic layer 162a can be simultaneously formed of the same material as the common layer of the organic layer 162. If the same emission layer is deposited on the entirety of the plurality of sub-pixels SP, the dummy organic layer 162a can be simultaneously formed of the same material as both the emission layer and the common layer of the organic layer 162. The organic layer 162 and the dummy organic layer 162a can be spaced apart from each other. Also, the organic layer 162 of the sub-pixel SP disposed over one side of the groove H and the organic layer 162 of the sub-pixel SP disposed over the other side of the groove H can be spaced apart from each other.

By the ends of the banks 170 and the ends of the first electrodes 161, the organic layer 162 of the sub-pixel SP disposed over one side of the groove H, the dummy organic layer 162a disposed on the bottom surface of the groove H, and the organic layer 162 of the sub-pixel SP disposed over the other side of the groove H can be formed to be discontinuous without being continuous. For example, the organic layer 162 and the dummy organic layer 162a can be disconnected between the plurality of sub-pixels SP by the ends of the banks 170 and the ends of the first electrodes 161. Accordingly, a current leakage phenomenon that can occur due to the common layer of the organic layer 162 can be minimized.

Referring to FIG. 3F, the second electrode 163 is formed on the organic layer 162. The second electrodes 163 of the respective sub-pixels SP adjacent to each other can be spaced apart from each other. Specifically, the second electrode 163 can be disposed only on the organic layer 162 and may not be formed in the undercut area UC covered by the first electrode 161 and the bank 170. For example, the second electrode 163 is not deposited on the side surface of the groove H and the bottom surface of the groove H facing the first electrode 161 and the bank 170.

The dummy conductive layer 163a can be deposited on an area of the bottom surface of the groove H that is not covered by the first electrode 161 and the bank 170. The dummy conductive layer 163a can be disposed to cover the dummy organic layer 162a. The dummy conductive layer 163a is a layer that is simultaneously formed of the same material as the second electrode 163. The second electrode 163 and the dummy conductive layer 163a can be spaced apart from each other. Also, the second electrode 163 of the sub-pixel SP disposed over one side of the groove H and the second electrode 163 of the sub-pixel SP disposed over the other side of the groove H can be spaced apart from each other.

By the ends of the banks 170 and the ends of the first electrodes 161, the second electrode 163 of the sub-pixel SP disposed over one side of the groove H, the dummy conductive layer 163a disposed on the bottom surface of the groove H, and the second electrode 163 of the sub-pixel SP disposed over the other side of the groove H can be formed to be disconnected without being continuous. For example, the second electrode 163 and the dummy conductive layer 163a can be disconnected between the plurality of sub-pixels SP by the ends of the banks 170 and the ends of the first electrodes 161. Accordingly, a current leakage phenomenon that can occur due to the common layer of the organic layer 162 can be minimized.

The exemplary embodiments of the present disclosure can also be described as follows:

According to an aspect of the present disclosure, a display device includes a substrate including a plurality of sub-pixels, an overcoating layer on the substrate and including a base portion and a plurality of protrusions having a groove, a first electrode corresponding to each of the plurality of sub-pixels and covering the base portion and the plurality of protrusions, a bank on a portion of the first electrode, an organic layer on the first electrode and the bank, a second electrode on the organic layer, and a dummy organic layer and a dummy conductive layer in the groove, wherein the groove is disposed between the plurality of sub-pixels, and wherein an end of the bank overlaps the groove.

An end of the first electrode can overlap the groove.

The end of the bank can cover a side surface of the first electrode.

The organic layer and the second electrode can be spaced apart from the dummy organic layer and the dummy conductive layer.

The organic layer can be disconnected from the dummy organic layer by the end of the bank, and the second electrode can be disconnected from the dummy conductive layer by the end of the bank.

The bank can be formed of an inorganic material, and the plurality of protrusions are formed of an organic material.

A lower surface of the bank and a lower surface of the first electrode can be exposed by the groove.

The bank disposed over one side of the groove and the bank disposed over another side of the groove can be spaced apart from each other.

A distance between the bank disposed over one side of the groove and the bank disposed over another side of the groove can be smaller than a width of the groove.

The first electrode and the bank can be not disposed in the groove.

The organic layer can include an emission layer and a common layer. The dummy organic layer can include the same material as the common layer. The dummy conductive layer can include the same material as the second electrode.

According to another aspect of the present disclosure, a display device includes a substrate including a plurality of sub-pixels, an overcoating layer on the substrate and including a base portion and a plurality of protrusions, a first electrode corresponding to each of the plurality of sub-pixels and covering the base portion and the plurality of protrusions, a bank on a portion of the first electrode and formed of an inorganic material, an organic layer on the first electrode and the bank, and a second electrode on the organic layer, wherein a part of the plurality of protrusions includes a groove between the plurality of sub-pixels, and an end of the bank is disposed to cover the groove at an outside of the groove.

An end of the first electrode can be disposed to cover the groove at the outside of the groove.

The end of the bank can cover a side surface of the first electrode.

The organic layer disposed over one side of the groove and the organic layer disposed over another side of the groove can be spaced apart from each other.

The second electrode disposed over one side of the groove and the second electrode disposed over another side of the groove can be spaced apart from each other.

The organic layer can include an emission layer and a common layer. The display device can further include a dummy organic layer including the same material as the common layer and disposed in the groove, and a dummy conductive layer including the same material as the second electrode and disposed to cover the dummy organic layer in the groove.

The dummy organic layer and the organic layer can be spaced apart from each other, and the dummy conductive layer and the second electrode can be spaced apart from each other.

The groove can include an undercut area exposing a lower surface of the first electrode and a lower surface of the bank.

A distance between the bank disposed over one side of the groove and the bank disposed over another side of the groove can be smaller than a width of the groove.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a plurality of sub-pixels;
an overcoating layer on the substrate and including a base portion and a plurality of protrusions having a groove;
a first electrode corresponding to each of the plurality of sub-pixels and covering the base portion and the plurality of protrusions;
a bank on a portion of the first electrode;
an organic layer on the first electrode and the bank;
a second electrode on the organic layer; and
a dummy organic layer and a dummy conductive layer in the groove,
wherein the groove is disposed between the plurality of sub-pixels, and
wherein an end of the bank overlaps the groove.

2. The display device of claim 1, wherein an end of the first electrode overlaps the groove.

3. The display device of claim 1, wherein the end of the bank covers a side surface of the first electrode.

4. The display device of claim 1, wherein the organic layer and the second electrode are spaced apart from the dummy organic layer and the dummy conductive layer.

5. The display device of claim 4, wherein the organic layer is disconnected from the dummy organic layer by the end of the bank, and
wherein the second electrode is disconnected from the dummy conductive layer by the end of the bank.

6. The display device of claim 1, wherein the bank is formed of an inorganic material, and the plurality of protrusions are formed of an organic material.

7. The display device of claim 1, wherein a lower surface of the bank and a lower surface of the first electrode are exposed by the groove.

8. The display device of claim 1, wherein the bank disposed over one side of the groove and the bank disposed over another side of the groove are spaced apart from each other.

9. The display device of claim 1, wherein a distance between the bank disposed over one side of the groove and the bank disposed over another side of the groove is smaller than a width of the groove.

10. The display device of claim 1, wherein the first electrode and the bank are not disposed in the groove.

11. The display device of claim 1, wherein the organic layer includes an emission layer and a common layer,
wherein the dummy organic layer includes a same material as the common layer, and
wherein the dummy conductive layer includes a same material as the second electrode.

12. A display device, comprising:
a substrate including a plurality of sub-pixels;
an overcoating layer on the substrate and including a base portion and a plurality of protrusions;
a first electrode corresponding to each of the plurality of sub-pixels and covering the base portion and the plurality of protrusions;
a bank on a portion of the first electrode and formed of an inorganic material;
an organic layer on the first electrode and the bank; and
a second electrode on the organic layer,
wherein a part of the plurality of protrusions includes a groove between the plurality of sub-pixels, and
wherein an end of the bank is disposed to cover the groove at an outside of the groove.

13. The display device of claim 12, wherein an end of the first electrode is disposed to cover the groove at the outside of the groove.

14. The display device of claim 12, wherein the end of the bank covers a side surface of the first electrode.

15. The display device of claim 12, wherein the organic layer disposed over one side of the groove and the organic layer disposed over another side of the groove are spaced apart from each other.

16. The display device of claim 12, wherein the second electrode disposed over one side of the groove and the second electrode disposed over another side of the groove are spaced apart from each other.

17. The display device of claim 12, wherein the organic layer includes an emission layer and a common layer, and
wherein the display device further comprises:
a dummy organic layer including a same material as the common layer, and disposed in the groove; and
a dummy conductive layer including a same material as the second electrode, and disposed to cover the dummy organic layer in the groove.

18. The display device of claim 17, wherein the dummy organic layer and the organic layer are spaced apart from each other, and the dummy conductive layer and the second electrode are spaced apart from each other.

19. The display device of claim 12, wherein the groove includes an undercut area exposing a lower surface of the first electrode and a lower surface of the bank.

20. The display device of claim 12, wherein a distance between the bank disposed over one side of the groove and the bank disposed over another side of the groove is smaller than a width of the groove.
